(19) United States
(12) Patent Application Publication
(10) Pub. No.: US 2005/0247978 A1
(43) Pub. Date: Nov. 10, 2005

(54) Solution-processed thin film transistor

(76) Inventors: Jian-gang Weng, Corvallis, OR (US); Ravi Prasad, Corvallis, OR (US); Cary G. Addington, Albany, OR (US); Man Ho Cheung, Singapore (SG)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/166,443

(22) Filed: Jun. 24, 2005

Related U.S. Application Data
(63) Continuation-in-part of application No. 10/617,114, filed on Jul. 9, 2003, now Pat. No. 6,927,108.

(51) Int. Cl. H01L 21/84; H01L 27/12

(52) U.S. Cl. 257/347; 438/149

(57) ABSTRACT

One exemplary embodiment of the present disclosure includes a solution-processed thin film transistor having a number of a number of conductive solution-processed thin film contacts, semiconductor solution-processed thin film active regions, and dielectric solution-processed thin film isolations formed in a sequence and organization to form a solution-processed thin film structure. One or more of the semiconductor solution-processed thin film active regions and the dielectric solution-processed thin film isolations have been selectively ablated.

### FIELD OF THE INVENTION

The present disclosure discusses embodiments with regard to the semiconductor field. The present disclosure particularly discusses solution-processed thin film transistors, devices utilizing such transistors, and methods of forming such transistors.

### BACKGROUND

This application is a continuation-in-part of U.S. application Ser. No. 10/617,114, filed Jul. 9, 2003, now allowed.

Solution-processed thin film transistors hold great promise to fundamentally change the semiconductor industry. Solution-processed, as applied to modify material and thin film and used herein, refers to those materials that are either soluble in a solution or capable of suspension in a solution so they may be processed by a solution technique, e.g., ink jet printing or spin coating, and formed into a thin film. Their uses run the gamut of transistor uses, and may be formed into light emitting structures. Materials used in the thin films, such as conductive polymers, are durable and can be flexible, thereby providing a range of uses in demanding environments.

The solution-processed thin film transistors also hold the potential to be fabricated by simple techniques, e.g., direct printing of circuits. A long-term goal is to have circuits of solution-processed thin film transistors printed on a substrate in similar fashion to the way ink is patterned in a printing press. Proposed manufacturing techniques seek to employ relatively simple procedures such as inkjet printing. A critical issue, however, remains feature size. Small feature sizes, e.g., small channel lengths, produce small threshold voltages and fast operation. However, introducing techniques to produce small feature sizes, e.g., lithography, may add complexity and expense that contradicts the goal of achieving simply manufactured devices and circuits.

Screen printing is an example technique for patterning drain and source regions of solution-processed thin film transistors. A gap of about 100 μm may be produced by this technique. Other techniques may produce smaller sized gaps, but have limitations such as being limited to use on small substrates. An example is a technique that converts portions of organic polymer materials to dielectric through selective use of UV radiation.

### BRIEF DESCRIPTION OF THE DRAWINGS

FIGS. 1A-1C are schematic block diagrams illustrating an exemplary embodiment formation method and solution-processed thin film transistor of the present disclosure;

FIG. 2A-2C are schematic block diagrams illustrating a second exemplary formation method and solution-processed thin film transistor of the present disclosure;

FIG. 3A-3C are schematic block diagrams illustrating a third exemplary formation method and solution-processed thin film transistor of the present disclosure;

FIGS. 4A and 4B illustrate an exemplary embodiment device isolation process for the FIGS. 1A-1C formation method; and

FIG. 5 illustrates an exemplary embodiment device isolation process for the FIGS. 2A-2C formation method.

FIG. 6A illustrates an exemplary embodiment of a display device having a number of transistors.

FIG. 6B illustrates another exemplary embodiment of a display device having a number of transistors.

FIG. 6C illustrates a circuit diagram of an exemplary embodiment of a display device having a number of transistors.

FIG. 7A illustrates an exemplary embodiment of an identification device having a number of transistors.

FIG. 7B illustrates a circuit diagram of an exemplary embodiment of an identification device having a number of transistors.

### DETAILED DESCRIPTION

An exemplary solution-processed thin film transistor of the present disclosure includes conductive solution-processed thin film contacts, semiconductor solution-processed thin film active regions, and dielectric solution-processed thin film isolations in a sequence and organization to provide a solution-processed thin film structure capable of transistor operation. During or after the formation of the transistor structure, laser ablation can be applied to one or more of the conductive solution-processed thin film contacts, the semiconductor solution-processed thin film active regions and the dielectric solution-processed thin film isolations to pattern or complete patterning of a material being selectively ablated.

Another exemplary embodiment provides a solution-processed thin film transistor having a number of conductive solution-processed thin film contacts, semiconductor solution-processed thin film active regions, and dielectric solution-processed thin film isolations formed in a sequence and organization to form a solution-processed thin film structure. The embodiment includes the feature that one or more of the semiconductor solution-processed thin film active regions and the dielectric solution-processed thin film isolations have been selectively ablated.

This process can be repeated to form transistors having a number of components and to form a plurality of thin film structures capable of transistor operation and further including a number of device isolations formed by ablating material between structures. Further, in some embodiments, the transistor can include one or more selectively ablated conductive solution-processed thin film contacts.

The transistor embodiments of the present disclosure can be used in many different fields and for many different functions. Some examples of these functions will be discussed in detail herein. For example, transistor embodiments can be used as sensors or switches. With respect to sensors applications, transistors can, for instance, be used to detect the presence of gas, moisture, and/or chemicals contacting the transistor and/or a change in temperature. This can be accomplished by using materials to fabricate at least a portion of the transistor out of materials sensitive to the item to be detected. The sensitivity can be measured, for example, by a change in the resistance and/or the current of the transistor.

The present disclosure also includes a number of display device embodiments. For example, in various embodiments, the display device can include an electro-optical device, a pixel controller for changing optical state of the pixel, and a solution-processed thin film transistor associated with the pixel controller. The solution-processed thin film transistor having a number of conductive solution-processed thin film contacts, semiconductor solution-processed thin film active regions, and dielectric solution-processed thin film isolations formed in a sequence and organization to form a solution-processed thin film structure where one or more of the semiconductor solution-processed thin film active regions and the dielectric solution-processed thin film isolations have been selectively ablated.

In such display device embodiments, transistors can be used to provide many different functions. For example, transistors can provide a logic function, such as being a part of a logic circuit of the pixel controller. Transistors can also provide switching functionality such as being a switch provided between the pixel controller and the electro-optical device.

The present disclosure also includes a number of identification device embodiments. For example, in various embodiments, the identification device can include a logic circuit, an antenna coupled to the logic circuit, and a solution-processed thin film transistor associated with the logic circuit. The solution-processed thin film transistor including a number of conductive solution-processed thin film contacts, semiconductor solution-processed thin film active regions, and dielectric solution-processed thin film isolations formed in a sequence and organization to form a solution-processed thin film structure where one or more of the semiconductor solution-processed thin film active regions and the dielectric solution-processed thin film isolations have been selectively ablated.

Identification devices can come in a variety of form factors, such as: tags, which can be hung or worn by an individual (e.g., necklace, bracelet, anklet, etc.); patches that can be attached to items to be identified and/or tracked; and labels that can be adhered to an item, for example.

In various embodiments, the identification device can communicate wirelessly with a remote device, for example, to provide information during an identification process. In some embodiments, the identification device communicates via radio frequency with a remote device, such as an RFID device (i.e., identification device) communicating with an RFID reader (i.e., remote device).

A remote device can be any suitable device for communicating with the identification device. For example, various remote devices, such as desktop, laptop, portable computing devices, or other devices having logic circuitry and the capability of communicating with the identification device, can be used with embodiments of the present disclosure. Additionally, transistors used in identification devices can be used for various purposes, such as a part of a logic circuit or as a switch.

Embodiments of the present disclosure also include solution-processed thin film transistors including drain, source, and gate contacts formed of conductive solution-processed thin film materials, a semiconductor solution-processed thin film material active region contacting the drain and source contacts and isolated from the gate contact by a dielectric solution-processed thin film material. In some embodiments, the transistor can be formed by a process including depositing, in a rough pattern, the drain and source contacts, and refining the rough pattern by selective laser ablation the semiconductor solution-processed thin film active region.

In such embodiments, the transistor can be formed by a process including refining the rough pattern to create a transistor channel. The transistor can also be formed by a process including refining the rough pattern through an optical mask to ablate multiple features simultaneously. In some embodiments, the transistor can be formed by a process including varying one or both of a laser wavelength and intensity during the laser ablation process.

The present disclosure also includes embodiments providing a solution-processed thin film transistor formation method. For example, in various embodiments, the method includes forming solution-processed thin film layers into a transistor structure, wherein the transistor structure includes a semiconductor solution-processed thin film active region, and a dielectric solution-processed thin film isolation. During the forming process, portions of the transistor structure may be patterned via laser ablation, using laser wavelength tuned to be absorbed by material being patterned and to minimally damage material underlying material being patterned. This process can be repeated to form a plurality of thin film structures capable of transistor operation and further including forming device isolations by ablating material between structures.

In various embodiments, methods can also include filling the device isolations with dielectric solution-processed thin film material

The present disclosure includes solution-processed thin film transistor formation that makes use of selective laser ablation to remove material as part of a patterning process, transistors formed by such processes, and devices having transistors therein. Solution-processed, as applied to modify material and thin film and used herein, refers to those materials that are either soluble in a solution or capable of suspension in a solution so they may be processed by a solution technique, e.g., ink jet printing or spin coating, and formed into a thin film. Exemplary categories of solution-processed thin films include organic thin films and polymer thin film categories.

For instance, the majority of the solution-processed materials that can be formed into thin films are the conductive polymers, semiconductive polymers, and dielectric polymers. However, a solution-processed material may also be a precursor of small organic molecular material that is soluble in a solvent. One example is the pentacene precursor that is soluble in chloroform. It can be spin-coated to form a thin film and then heated to reduce to pentacene, for example, at temperatures of ˜200 C. Pentacene is an organic semiconductor but is not a polymer. Also, there may be inorganics that may be solution-processed to form thin films.

In exemplary embodiments, a solution based processing is used to roughly pattern a portion of a solution-processed thin film transistor being formed. For example, solution processing techniques may form into rough pattern conductive solution-processed thin film contacts, semiconductor solution-processed thin film active regions, or dielectric solution-processed thin film isolations in a sequence and organization to form a solution-processed thin film structure capable of transistor operation.

Patterning of contacts, active regions, or isolations may be refined by selective laser ablation. For example, the ablation can be tuned to a wavelength to achieve maximum absorption by the material being ablated and to minimize damage to material under the material being ablated. In other embodiments of the present disclosure, laser ablation can be used to partially or to completely pattern a contact, active region, and/or dielectric.

In such embodiments, rough patterning in the solution based processing deposition may be unnecessary. As an example, conductive polymer material is deposited by solution based processing without a pattern. Selective laser ablation then is used to pattern contacts, e.g., circuit interconnect patterns, in the solution-processed conductive material. The laser radiation may also be directed through an optical mask, permitting the formation of relatively complex patterns simultaneously, e.g., the ablation of multiple channel areas, on one or more transistors, at the same time.

The embodiments of the present disclosure will now be illustrated with respect to exemplary embodiment thin film transistor devices. In describing the embodiments of the present disclosure, particular exemplary devices and device applications will be used for purposes of illustration, but the embodiments of the present disclosure are not limited to the formation of the particular illustrated devices.

Dimensions and illustrated devices may be exaggerated for purposes of illustration and understanding of the embodiments of the present disclosure. Reference numerals may be used in different embodiments to indicate similar features. The elements of the drawings are not necessarily to scale relative to each other. Rather, emphasis has instead been placed upon clearly illustrating the embodiments of the present disclosure. A device illustrated in one fashion by a two-dimensional schematic layer structure will be understood by artisans to provide teaching of three-dimensional device structures and integrations, for example.

The exemplary embodiments may be constructed with any combination of solution-processed electronic materials capable of being formed into thin films. By way of example, poly (e.g., 3, 4-ethylenedioxythiophene), also called PEDOT, is a conductive polymer suitable for drain, gate, and source contacts. An exemplary suitable semiconductive polymer is poly (3-hexylthiophene-2, 5-diyl), also called P3HT. An exemplary dielectric polymer is poly (vinylphenol), also called PVP. Other suitable exemplary polymer materials, like the above examples, will exhibit the ability to be solution processed and formed into very thin films.

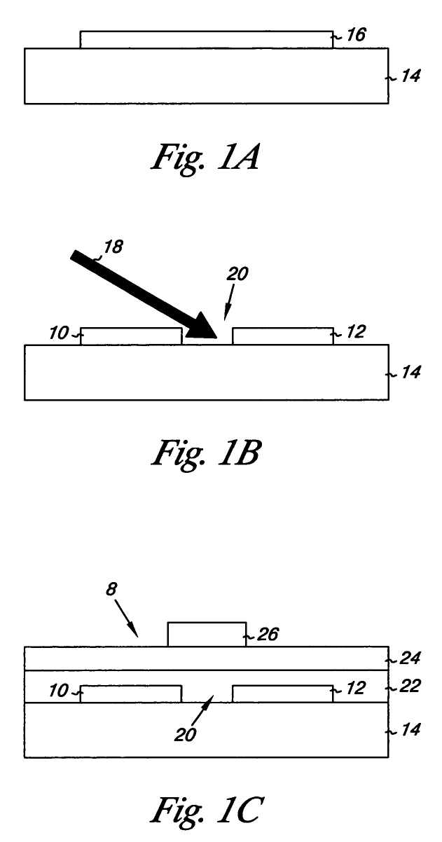

Referring now to FIGS. 1A-1C, an exemplary embodiment formation method and solution-processed thin film transistor 8 of the present disclosure are illustrated. The transistor 8 has source and drain contacts 10, 12 formed upon a substrate 14. In various embodiments, the substrate 14 should have good dielectric properties and be compatible with the solution-processed thin film materials used to form the transistor 8. Suitable exemplary substrates include glass, polycarbonate, polyarylate, polyethylenterephtalate (PET), polyestersulfone (PES), polyimide, polyolefin, and polyethylene naphtthalate (PEN), among others.

As illustrated in FIG. 1A, initially, conductive solution-processed thin film material 16 can be deposited upon the substrate 14 (e.g., by inkjet printing). As an example, though a single device is illustrated, the conductive solution-processed thin film material 16 may be formed into a rough pattern such as a circuit interconnect pattern used to connect multiple transistors. After a rough patterned deposit of the conductive solution-processed thin film material 16, refined patterning can be conducted by laser ablation, as illustrated in FIG. 1B.

In FIG. 1B, laser irradiation 18 tuned to a wavelength that will be selectively absorbed by the conductive solution-processed thin film material 16 can be used to pattern a transistor channel 20 between the source and drain contacts 10 and 12. To reduce threshold voltage, the channel can be made narrow, e.g., less than 5 μm. Of course, some device architectures permit wider channels, and the maximum channel width is dependent upon device architecture. As for minimum channel width, channel widths of less than 1 μm, for example, can be formed with optimization of laser wavelengths and focusing optics depending upon the particular solution-processed materials used. Properly tuned laser radiation can ablate the conductive solution-processed thin film material and have a minimal or no effect on the underlying material, i.e., the substrate 14 in FIGS. 1A-1C.

As shown in FIG. 1C, after the transistor channel is formed 20, a thin film of semiconductor solution-processed thin film material can be deposited to form an active region thin film layer 22 over the source and drain contacts and exposed portions of the substrate 14. Semiconductor material deposits into the transistor channel 20 during this part of the formation process.

Formation of the thin film layer may be conducted by a suitable solution processed deposition. For example, spin coating is an exemplary suitable deposition technique. Spin coating can also be utilized for the deposition of a dielectric solution-processed thin film material to form an isolation layer 24 over the active region thin film layer 22. Conductive solution-processed thin film material is then deposited upon the isolation layer 24 to form a gate contact 26.

The gate contact deposit can be accomplished by inkjet printing. In addition, there may be a rough deposition of the gate contact 26 followed by selective ablation for refining the pattern. The gate contact 26 may form part of a circuit interconnect pattern, as well.

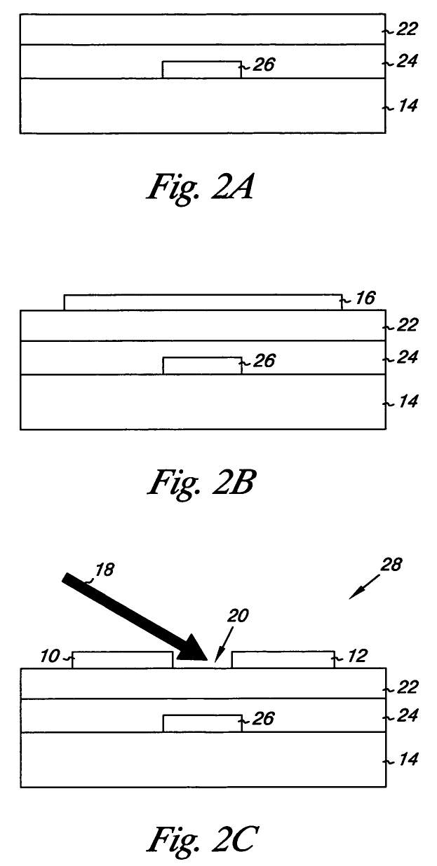

Referring now to FIGS. 2A-2C, a second exemplary embodiment formation method and solution-processed thin film transistor 28 of the present disclosure are illustrated. Initially, conductive solution-processed thin film material can be patterned upon the substrate 14 to form a gate contact 26. As in the FIGS. 1A-1C embodiment, the gate contact 26 may be patterned roughly by a deposit and then refined by laser ablation. The gate contact 26 may also form part of a circuit interconnect pattern.

A dielectric solution-processed thin film material thin film layer 24 can then be formed over the gate contact 26 and exposed portions of the substrate. This can then be followed by deposit of a semiconductor solution-processed thin film material active region thin film layer 22. In FIG. 2B, conductive solution-processed thin film material 16 can be deposited on the semiconductor active region thin film layer 22.

In FIG. 2C, laser irradiation 18, tuned to a wavelength that can be selectively absorbed by the conductive solution-processed thin film material 16, can be used to pattern a transistor channel 20 between the source and drain contacts 10 and 12. The transistor channel 20 can operate in the active region thin film layer 22, but the gap between the source and drain contacts 10 and 12 and created by the ablation defines the channel location in the embodiment of FIG. 2C.

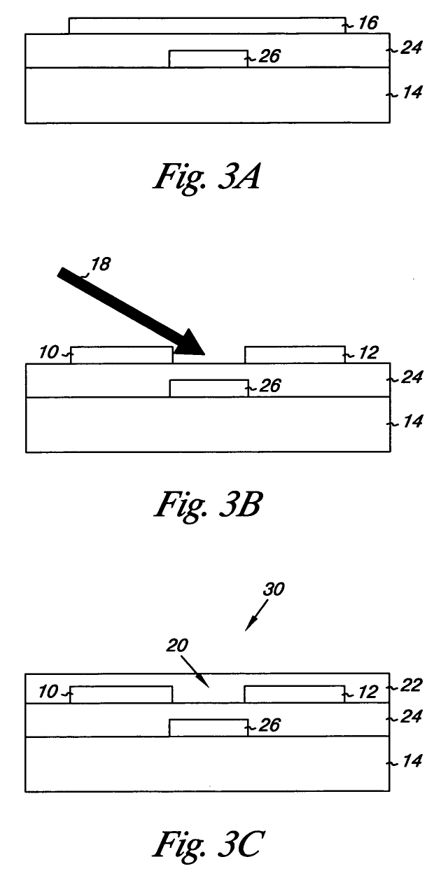

Referring now to FIGS. 3A-3C, a third exemplary embodiment formation method and solution-processed thin film transistor 30 of the present disclosure are illustrated. Initially, conductive solution-processed thin film material can be patterned upon the substrate 14 to form a gate contact 26. As in the other embodiments, the gate contact 26 may be patterned roughly by a deposit and then refined by laser ablation. The gate contact 26 may also form part of a circuit interconnect pattern.

A dielectric solution-processed thin film material thin film layer 24 can then be formed over the gate contact 26 and exposed portions of the substrate. Conductive solution-processed thin film material 16 can be deposited on the dielectric solution-processed thin film material layer 24.

In FIG. 3B, laser irradiation 18, tuned to a wavelength that can be selectively absorbed by the conductive solution-processed thin film material 16, can be used to pattern a transistor channel 20 between the source and drain contacts 10 and 12. In FIG. 3C, a semiconductor solution-processed thin film material can then be deposited over the source and drain contacts and exposed portions of the dielectric solution-processed thin film material layer to form semiconductor solution-processed thin film material active region thin film layer 22.

The resultant transistors illustrated in FIGS. 1C, 2C, and 3C can be utilized in many different fields and for a variety of different functions. For example, such transistors may be suitable for use in display devices, identification devices, and as sensors, among other fields of use.

In sensor embodiments, a portion of the transistor can be formed from a material that is sensitive to a particular item, such as temperature, light, moisture, one or more gases, and/or one or more chemicals. For example, in the transistor illustrated in FIG. 2C, the portion of the semiconductor active region thin film layer 22 that forms the bottom of the channel 20 can be fabricated from a material that increases its resistance when the material is in contact with moisture. This increase of resistance, or the decrease of drain-source current, can be used to indicate that moisture is present. In some embodiments another change of device characteristics can be used as an indicator.

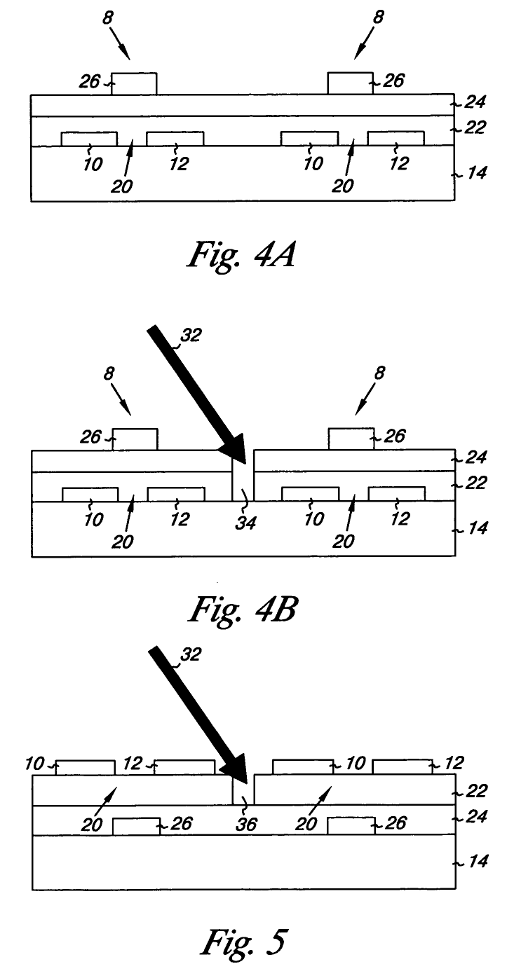

FIGS. 4A and 4B illustrate an exemplary embodiment device isolation process for the FIGS. 1A-1C formation method embodiment. FIG. 4A illustrates two transistor devices 8 formed in accordance with FIGS. 1A-1C. The transistor devices 8 are formed as part of a single integration. In FIG. 4B laser irradiation 32 is tuned and controlled to ablate layers down to the substrate 14. The laser radiation may be varied in intensity or wavelength during the ablation of multiple layers. The ablation thereby creates a device isolation 34.

In FIG. 4B, the device isolation takes the form of a gap. The gap may also be filled with isolation material, such as dielectric solution-processed thin film material.

FIG. 5 illustrates a device isolation process for two transistor devices 28 formed in accordance with FIGS. 2A-2C. In the exemplary embodiment of FIG. 5, the laser irradiation is tuned and controlled to form a device isolation 36 through the semiconductor layer up to the dielectric solution-processed thin film material layer 24. An optical mask may be used to create multiple features simultaneously, such as multiple device isolations 36. As in FIGS. 4A and 4B, the device isolation takes the form of a gap and also may be filled with isolation material.

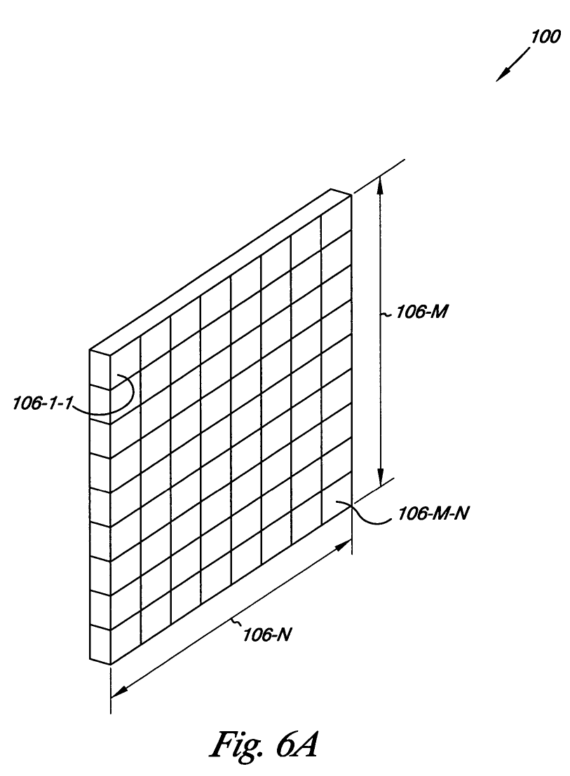

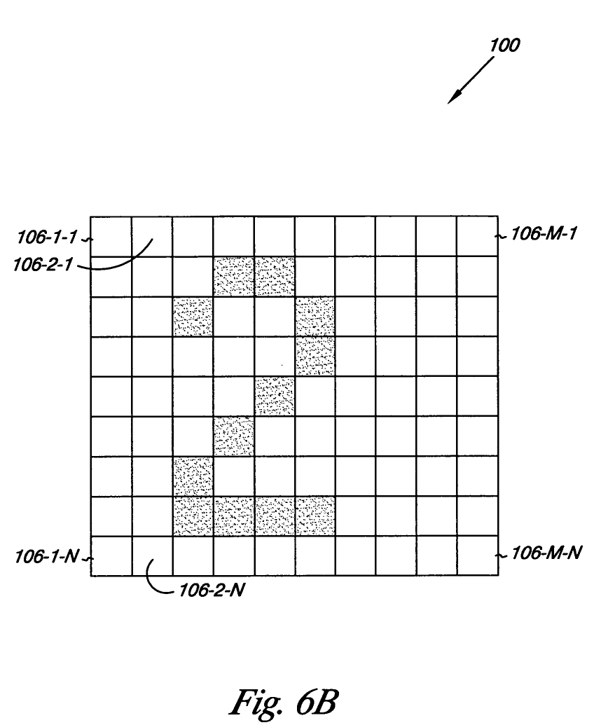

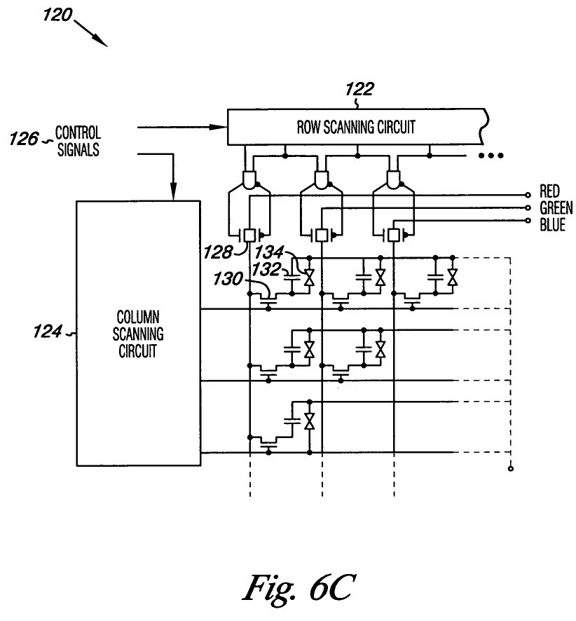

FIG. 6A illustrates an exemplary embodiment of a display device having a number of transistors. Transistors can be used in display devices, such as Liquid Crystal Display (LCD) or Organic Light Emitting Diode (OLED) display shown in FIGS. 6A and 6B, to provide a variety of functions. For example, embodiments of the present disclosure can be used as switches used throughout the display device including in logic circuits used for controlling various functions of the display device and can be used in electro-optical components such as light emitters, shutters, transmitters, and/or receivers, among other components of the device. One such function is shown in FIG. 6C for purposes of illustrating how such transistors can be used. However, display devices can use transistors in many other ways and the present disclosure should not be considered to limit the claims to the embodiment shown in FIG. 6C.

In various embodiments, such as that shown in FIGS. 6A and 6B, the display device can include a matrix of pixel cells 106 having M columns and N rows. For example, as shown in FIG. 6A, pixel cell 106-1-1 includes a pixel cell positioned in the first column and the first row of the display device 100 and pixel cell 106-M-N includes a pixel cell positioned in the last column and the last row of the display device 100. The designators M and N can each represent any number, and the use of such designators for these elements should not be viewed as limiting the quantities of the other elements illustrated or described herein.

It will be appreciated from reading the present disclosure that displays having small numbers of pixel cells are illustrated in various FIGS. 6A and 6B for the sake of providing a clear example for the reader and that the embodiments of the present disclosure can include a display having more or less pixel cells and other components. For example, one suitable design includes a display device having a resolution of 768×1024, i.e., 768 rows and 1024 columns of pixel cells. As used herein, a number of pixel cells can include the total number of pixel cells on a display device. Thus, if a display device includes a resolution of 768 rows and 1024 columns, such as in an XGA monitor, the group of pixel cells in each row would include 768 pixel cells, and N=768.

FIG. 6B illustrates another exemplary embodiment of a display device having a number of transistors. As shown in the embodiment of FIG. 6B, the display device 100 displays an image in the form of a number two. To form the image of the number two, a number of pixel cells within the various groups of pixel cells on the display device change their optical states (e.g., change transmittance, change color, or emit light). The change in optical states can be based on activating the portion of pixel arrays that are to be used to form the number two. The activation of the pixel cells is based on the signal received by each pixel.

FIG. 6C illustrates a circuit diagram of an exemplary embodiment of a display device 120 having a number of transistors. In particular, this embodiment represents an electronic circuit of an active matrix LCD panel. In this embodiment, a plurality of thin film transistor switches are coupled to a column scanning circuit 124 via a number of gate lines, to a row scanning circuit 122 by a number of signal lines, and to a common voltage via a common electrode. Each switch 130 is formed by a thin film transistor 130, a capacitance element 132 and a pixel electrode. Local liquid crystal material is disposed between the pixel electrode and the common electrode 134 (double triangle symbol is positioned to represent the interface between the common and pixel electrodes) in parallel to the capacitance element 132.

The gate lines are connected to the row scanning circuit 124 enabling the gate lines to be scanned. The signal lines are similarly connected respectively through scanning switches 128 to respective input lines for red, green and blue video signals. Thus each switch and local liquid crystal material defines a sub-pixel for a given color.

The three sub-pixels for the three colors define a pixel area. Typically each sub-pixel is oval or rectangular in shape, while the three sub-pixels forming the pixel generally define a square shape. By driving the switch and selectively applying voltage to the pixel electrode through the transistor 130, an electrical field is created which changes the orientation of the liquid crystal material. Selective control of the switches thus leads to control of the liquid crystal in each pixel area so as to form a desired image.

Circuitry can control such structure through hardware circuitry that uses solid state logic, for example, or through computer executable instructions or a combination of the two. For instance, circuitry, such as data processing circuitry, can receive encoded data, decode the encoded data, and convey the decoded data to one, multiple, and/or groups of pixel cells. Circuitry can also be used to provide control signals 126. The sending, receiving, decoding, and conveying functions can also be accomplished by computer executable instructions or a combination of hardware and software.

In these embodiments, a processor can be provided to control a number of display device functions. Processors and other logic circuit can incorporate transistors and described in the embodiments of the present disclosure.

The display device can also include memory in some embodiments. The memory can be used, for example, to hold the computer executable instructions and other information useful in providing the above described functions. Memory can include the various volatile and non-volatile memory types, such as ROM, RAM, and flash memory, for example. Computer readable medium, as it is used herein, includes the various types of memory within a display system or device.

In various embodiments, the signals regarding when a pixel cell is to be illuminated can be conveyed to the pixel cells. For example, in some embodiments, a transmitter transmits encoded data regarding the illumination of a pixel and the display device circuitry decodes the encoded data and conveys the decoded data to one or more pixel cells to activate each pixel cell. As used herein, activating means to illuminate one or more pixel cells based upon the signal received. In various embodiments, pixel cell 106-1-1 can include circuitry for receiving and interpreting a signal.

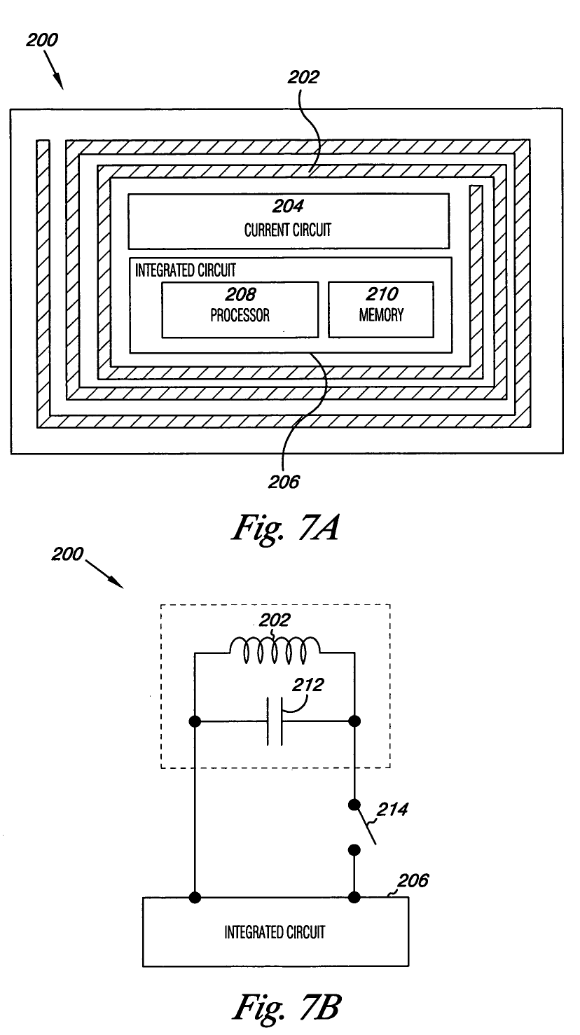

FIG. 7A illustrates an exemplary embodiment of an identification device having a number of transistors. FIG. 7A illustrates identification device 200, in this example an RFID tag. In particular, the exemplary embodiment is a contact-less thin film integrated circuit that has an antenna 202, a current circuit 204, and an integrated circuit area 206 including a logic circuit 208 (in this example a processor) a memory 210, and the like. The antenna 202 is connected to the logic circuit 208 through the current circuit 204. The current circuit 204 and the integrated circuit 206 can each include transistors for providing various functionality of the device 200. The current circuit 204, for example, has a structure including one or more transistors and capacitors, for providing the function of converting an alternating current (AC) cycle which antenna receives into direct current (DC). As stated above, various forms of logic circuitry including components on an integrated circuit can include transistors described with respect to the embodiments of the present disclosure. Accordingly, the integrated circuit 206 can include one or more transistors.

FIG. 7B illustrates a circuit diagram of an exemplary embodiment of an identification device 200 having a number of transistors. In this embodiment, an embodiment of a transistor 214, as described in the present disclosure, is used as a switch to connect the electrical circuit between the antenna 202 and capacitor 212 and the integrated circuit 206.

While specific embodiments of the present disclosure have been shown and described, it should be understood that other modifications, substitutions and alternatives are apparent to one of ordinary skill in the art. Such modifications, substitutions and alternatives can be made without departing from the spirit and scope of the present disclosure, which should be determined from the appended claims.

Although specific embodiments have been illustrated and described herein, it is to be understood that the above descriptions have been made in an illustrative fashion and not a restrictive one. Those of ordinary skill in the art will appreciate that an arrangement calculated to achieve the same results with different permutations of the disclosed techniques can be substituted for the specific embodiments shown or described. The scope of the various embodiments of the present disclosure includes other applications in which the devices, methods, and systems described herein are utilized. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the embodiments of the invention require more features than are expressly recited in each claim. Rather, as the following claims reflect, inventive subject matter may lie in less than all features of a single disclosed embodiment. Thus, the following claims are hereby incorporated into the Detailed Disclosure by reference, with each claim standing on its own as a separate embodiment.

1. A solution-processed thin film transistor, comprising:
a number of conductive solution-processed thin film contacts, semiconductor solution-processed thin film active regions, and dielectric solution-processed thin film isolations formed in a sequence and organization to form a solution-processed thin film structure; and
wherein one or more of the semiconductor solution-processed thin film active regions and the dielectric solution-processed thin film isolations have been selectively ablated.

2. The transistor of claim 1, wherein the formation and selective ablation have been repeated to form a plurality of thin film structures capable of transistor operation and further including a number of device isolations formed by ablating material between structures.

3. The transistor of claim 1, wherein the transistor includes a selectively ablated conductive solution-processed thin film contact.

4. The transistor of claim 1, wherein a portion of the transistor is constructed from a material that can be utilized to sense moisture contacting the transistor.

5. The transistor of claim 1, wherein a portion of the transistor is constructed from a material that can be utilized to sense a gas contacting the transistor.

6. The transistor of claim 1, wherein a portion of the transistor is constructed from a material that can be utilized to sense a chemical contacting the transistor.

7. The transistor of claim 1, wherein a portion of the transistor is constructed from a material that can be utilized to sense a temperature on a surface of the transistor.

8. A display device comprising:
an electro-optical component;
a pixel controller associated with the electro-optical component for changing an optical state of a pixel; and
a solution-processed thin film transistor associated with the pixel controller, including:
a number of conductive solution-processed thin film contacts, semiconductor solution-processed thin film active regions, and dielectric solution-processed thin film isolations formed in a sequence and organization to form a solution-processed thin film structure; and
wherein one or more of the semiconductor solution-processed thin film active regions and the dielectric solution-processed thin film isolations have been selectively ablated.

9. The display device of claim 8, wherein the solution-processed thin film transistor is a part of a logic circuit of the pixel controller.

10. The display device of claim 8, wherein the solution-processed thin film transistor is a switch provided between the pixel controller and the electro-optical component.

11. The display device of claim 8, wherein the solution-processed thin film transistor is a part of the electro-optical component.

12. The display device of claim 8, wherein the electro-optical component is a light emitter.

13. The display device of claim 8, wherein the electro-optical component is a shutter.

14. The display device of claim 8, wherein the electro-optical component is a transmitter.

15. An identification device comprising:
a logic circuit;
an antenna coupled to the logic circuit; and
a solution-processed thin film transistor associated with the logic circuit, including:
a number of conductive solution-processed thin film contacts, semiconductor solution-processed thin film active regions, and dielectric solution-processed thin film isolations formed in a sequence and organization to form a solution-processed thin film structure; and
wherein one or more of the semiconductor solution-processed thin film active regions and the dielectric solution-processed thin film isolations have been selectively ablated.

16. The identification device of claim 15, wherein a form factor for the device is selected from the group including:
a tag;
a patch; and
a label.

17. The identification device of claim 15, wherein the identification device communicates wirelessly with a remote device.

18. The identification device of claim 15, wherein the identification device communicates via radio frequency with a remote device.

19. The identification device of claim 15, wherein the solution-processed thin film transistor is a part of a logic circuit of the processor.

20. The identification device of claim 15, wherein the solution-processed thin film transistor is a switch provided between the processor and the antenna.

21. A solution-processed thin film transistor including drain, source, and gate contacts formed of conductive solution-processed thin film materials, a semiconductor solution-processed thin film material active region contacting the drain and source contacts and isolated from the gate contact by a dielectric solution-processed thin film material, the transistor being formed by a process comprising:
depositing, in a rough pattern, the drain and source contacts, and
refining the rough pattern by selective laser ablation the semiconductor solution-processed thin film active region.

22. The transistor of claim 21, wherein the transistor is formed by a process including refining the rough pattern to create a transistor channel.

23. The transistor of claim 21, wherein the transistor is formed by a process including refining the rough pattern through an optical mask to ablate multiple features simultaneously.

24. The transistor of claim 21, wherein the transistor is formed by a process including varying one or both of a laser wavelength and intensity during the laser ablation process.

25. A solution-processed thin film transistor formation method, the method comprising:
forming solution-processed thin film layers into a transistor structure, wherein the transistor structure includes a semiconductor solution-processed thin film active region, and a dielectric solution-processed thin film isolation;
during the forming, patterning portions of the transistor structure via laser ablation, using laser wavelength tuned to be absorbed by material being patterned and to minimally damage material underlying the material being patterned; and
repeating the forming and patterning to form a plurality of thin film structures capable of transistor operation and further including forming device isolations by ablating material between structures.

26. The method of claim 25, further including filling the device isolations with dielectric solution-processed thin film material.
